(19) United States
(12) Patent Application Publication
(10) Pub. No.: US 2013/0155364 A1
(43) Pub. Date: Jun. 20, 2013

(54) METHOD OF REDUCING PARASITIC CAPACITANCE OF LIQUID CRYSTAL DISPLAY DEVICE AND LIQUID CRYSTAL DISPLAY DEVICE

(71) Applicants: Chengcai Dong, Shenzhen (CN); Jehao Hsu, Shenzhen (CN); Jingfeng Xue, Shenzhen (CN); Xiaohui Yao, Shenzhen (CN)

(72) Inventors: Chengcai Dong, Shenzhen (CN); Jehao Hsu, Shenzhen (CN); Jingfeng Xue, Shenzhen (CN); Xiaohui Yao, Shenzhen (CN)

(73) Assignee: SHENZHEN CHINA STAR OPTOELECTRONICS TECHNOLOGY CO.,LTD., Shenzhen (CN)

(21) Appl. No.: 13/380,886

(22) PCT Filed: Dec. 16, 2011
(86) PCT No.: PCT/CN2011/084142

§ 371 Date: Dec. 26, 2011

(30) Foreign Application Priority Data
Dec. 14, 2011 (CN) 201110418175.0

(51) Int. Cl. G02F 1/1343; H01L 21/00

(52) U.S. Cl. 349/139; 438/30; 257/E21.001

(57) ABSTRACT

A method of reducing parasitic capacitance of liquid crystal display device is disclosed where the liquid crystal display device comprises a first substrate, a second substrate and a liquid crystal layer. The first substrate comprises data lines and a first transparent electrode, and the second substrate is provided with a second transparent electrode. The method comprises the following steps: A. by means of photolithography and patterning, the second transparent electrode is separated into a primary second transparent electrode and a secondary second transparent electrode; B. offering the secondary second transparent electrode the same signal to the relevant data line. The invention further relates to a liquid crystal display device and the parasitic capacitance in the data lines of the liquid crystal display device can be diminished.

### BACKGROUND OF THE INVENTION

1. Field of the Invention

The present invention relates to liquid crystal display domain. More particularly, the present invention relates to a method of reducing parasitic capacitance of liquid crystal display device and the liquid crystal display device.

2. Description of the Prior Art

FIG. 1 is a schematic diagram of the structure of the liquid crystal display device of prior art techniques, and FIG. 2 is an equivalent circuit of the liquid crystal display device of prior art techniques. FIG. 3 is an equivalent circuit of the display pixel of the liquid crystal display device of prior art techniques. Referring to FIGS. 1-3, in regular liquid crystal display devices 100, multiple data lines 111 are formed on the TFT substrate 110 positioned parallel one another, and the multiple gate lines 101 are formed in an insulation layer and cross over the data lines 111. Thin film transistors 102 each is formed at the proximity of the intersection of a data line 111 and a gate line 101 where the drain of the thin film transistor 102 is connected to the data line 111, the gate of the thin film transistor 102 is connected to the gate line 101, and the source of the thin film transistor 102 is connected to the pixel electrode 103 (the first transparent electrode). The liquid crystal layer 130 is disposed in between the pixel electrode 103 and an opposite electrode 121 (the second transparent electrode), to form a liquid crystal capacitance 104. The opposite electrode 121 is disposed on the other substrate 120, and an opposite voltage is applied to the opposite electrode 121 to drive liquid crystal molecules of the liquid crystal layer 130 to rotate.

The liquid crystal display device 100, data lines 111 and the opposite electrode 121 fabricated by the aforementioned method are prone to bring about parasitic capacitance, which causes signal delay of the data lines 111. Supposing that the parasitic capacitance of the data line 111 is oversized, serious signal delay would give rise to color spots on the liquid crystal display device 100.

Accordingly, it is quite essential to provide a method of reducing parasitic capacitance of liquid crystal display device and the liquid crystal display device, to settle the existing issues of conventional techniques.

### SUMMARY OF THE INVENTION

The objective of the present invention is to provide a method of reducing parasitic capacitance of data lines and an accompanying liquid crystal display device, to settle the technical issue occurred by oversized parasitic capacitance of the data line of the liquid crystal display device that gives rise to color spots on the liquid crystal display device.

To settle the aforementioned issue, the present invention provides a technical solution as follows:

The present invention relates to a method of reducing parasitic capacitance of liquid crystal display device, where the liquid crystal display device comprises a first substrate, a second substrate and a liquid crystal layer disposed in between the first substrate and the second substrate. The first substrate comprises data lines and a first transparent electrode, and the second substrate is provided with a second transparent electrode. The method comprises the following steps: A. by means of photolithography and patterning, the second transparent electrode is separated into a primary second transparent electrode and a secondary second transparent electrode; B. offering the secondary second transparent electrode the same signal to the relevant data line; the secondary second transparent electrode is located at a location on the second substrate that corresponds to the relevant data line, and the primary second transparent electrode is located aside to the location on the second substrate that corresponds to the relevant data line; the step B, more specifically, is to connect the secondary second transparent electrode to the signal input of the relevant data line, or to the relevant data line.

The present invention relates to a method of reducing parasitic capacitance of liquid crystal display device, where the liquid crystal display device comprises a first substrate, a second substrate and a liquid crystal layer disposed in between the first substrate and the second substrate. The first substrate comprises data lines and a first transparent electrode, and the second substrate is provided with a second transparent electrode. The method comprises the following steps: A. by means of photolithography and patterning, the second transparent electrode is separated into a primary second transparent electrode and a secondary second transparent electrode; B. offering the secondary second transparent electrode the same signal to the relevant data line; the secondary second transparent electrode is located at a location on the second substrate that corresponds to the relevant data line, and the primary second transparent electrode is located aside to the location on the second substrate that corresponds to the relevant data line.

In the method of reducing parasitic capacitance of liquid crystal display device of the present invention, the step B specifically is to connect the second transparent electrode to the signal input of the relevant data line.

In the method of reducing parasitic capacitance of liquid crystal display device of the present invention, the step B specifically is to connect the second transparent electrode to the relevant data line.

In the method of reducing parasitic capacitance of liquid crystal display device of the present invention, the connection between the second transparent electrode and the relevant data line is specifically embodied by connecting the second transparent electrode to the relevant data line through a transfer.

In the method of reducing parasitic capacitance of liquid crystal display device of the present invention, the transfer is disposed at inactive area of the liquid crystal display device.

In the method of reducing parasitic capacitance of liquid crystal display device of the present invention, the connection between the second transparent electrode and the relevant data line is specifically embodied by connecting the second transparent electrode to the relevant data line through a conductive post.

In the method of reducing parasitic capacitance of liquid crystal display device of the present invention, the conductive post is disposed at active area of the liquid crystal display device.

The present invention further relates to a liquid crystal display device, comprising: a first substrate, a second substrate and a liquid crystal layer disposed in between the first substrate and the second substrate. The first substrate comprises data lines and a first transparent electrode, and the second substrate is provided with a second transparent electrode. The second transparent electrode comprises a primary second transparent electrode and a secondary second transparent electrode. The secondary second transparent electrode is to receive the signal of the relevant data line and is located at a location on the second substrate that corresponds to the relevant data line while the primary second transparent electrode is located aside to the location on the second substrate that corresponds to the relevant data line.

In the liquid crystal display device of the present invention, the secondary second transparent electrode is connected to the signal input of the relevant data line.

In the liquid crystal display device of the present invention, the secondary second transparent electrode is connected to the relevant data line.

In the liquid crystal display device of the present invention, the secondary second transparent electrode is connected to the relevant data line through a transfer.

In the liquid crystal display device of the present invention, the transfer is disposed at an inactive area of the liquid crystal display device.

In the liquid crystal display device of the present invention, the secondary second transparent electrode is connected to the relevant data line through a conductive post.

In the liquid crystal display device of the present invention, the conductive post is disposed at an active area of the liquid crystal display device.

The advantages of the realization of the present invention comprise: substantially reducing the parasitic capacitance between the data line and the primary second transparent electrode, which subsides the signal delay of the data line, to avoid color spots due to oversized parasitic capacitance in the data line of the liquid crystal display device.

This invention is detailed described with reference to the following preferred embodiments and the accompanying drawings for better comprehension.

### BRIEF DESCRIPTION OF THE DRAWINGS

FIG. 1 is a schematic diagram of the structure of a liquid crystal display device of conventional techniques;

FIG. 2 is a diagram of the equivalent circuits of the liquid crystal display device of conventional techniques;

FIG. 3 is a diagram of the equivalent circuits of a display pixel of the liquid crystal display device of conventional techniques;

FIG. 4 is a schematic diagram of the structure of the liquid crystal display device of the first preferred embodiment of the present invention;

FIG. 5 is a flowchart of the method of reducing parasitic capacitance of the liquid crystal display device of the preferred embodiment of the present invention;

FIG. 6 is a schematic diagram of the structure of the liquid crystal display device of the second preferred embodiment of the present invention; and

FIG. 7 is a schematic diagram of the structure of the liquid crystal display device of the third preferred embodiment of the present invention.

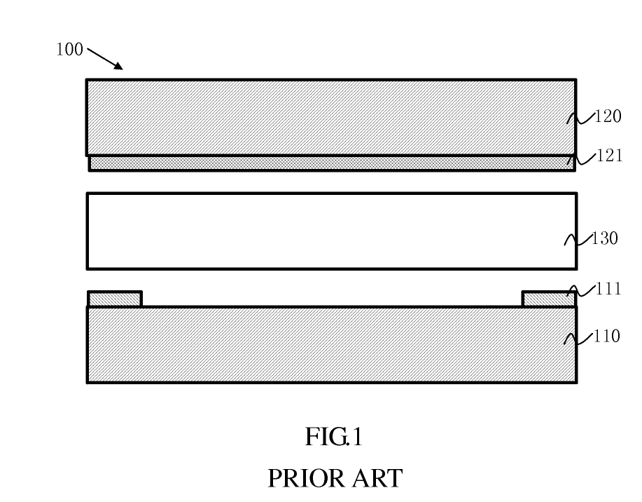

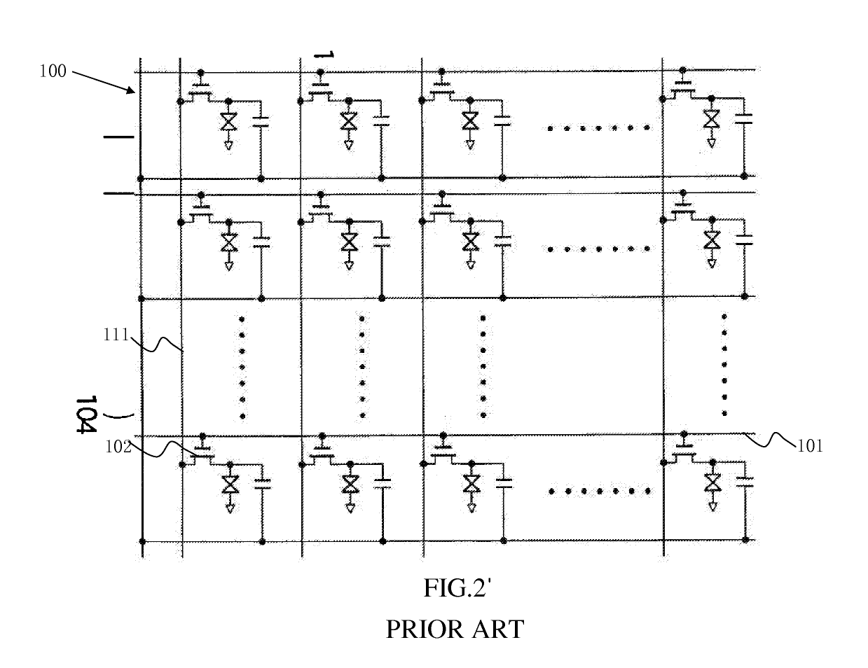

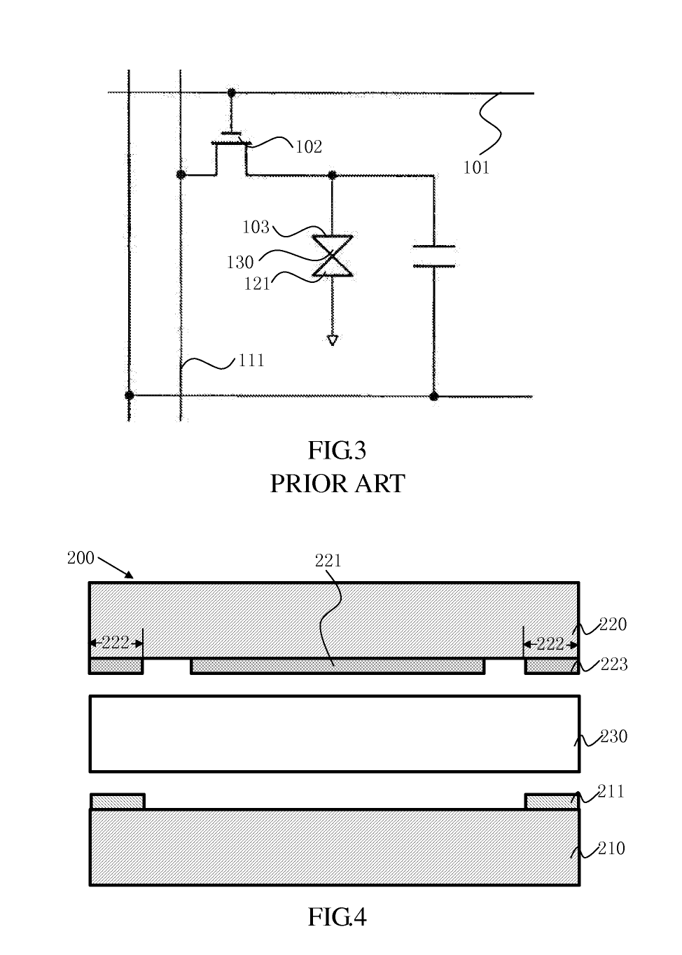

### DETAILED DESCRIPTION OF THE INVENTION

The following embodiments are described with reference to the following accompanying drawings which exemplify the realizations of this invention.

FIG. 4 is a schematic diagram of the structure of the liquid crystal display device of the first preferred embodiment of the present invention. In the present embodiment, the liquid crystal display device 200 comprises a first substrate 210, a second substrate 220 and a liquid crystal layer 230 disposed in between the first substrate 210 and the second substrate 220. The first substrate 210 comprises data lines 211 and a first transparent electrode (not shown in the figures), and the second substrate 220 is provided with a second transparent electrode. The second transparent electrode comprises a primary second transparent electrode 221 and a secondary second transparent electrode 223. The secondary second transparent electrode 223 is located at a location 222 on the inner surface of the second substrate 220 that corresponds to the relevant data line 211, and the primary second transparent electrode 221 is located aside to the location 222 on the inner surface of the second substrate 220 that corresponds to the relevant data line 211, and that means the primary second transparent electrode 221 is not covered by the location 222. The secondary second transparent electrode 223 is used to receive the signal of the relevant data line 211. In the present embodiment, the first substrate 210 can be a glass substrate or a substrate of other substance that is provided with a thin film transistor (TFT) array, and the second substrate 220 can be a glass substrate or a substrate of other substance that is provided with a color filter (CF) layer. It is worth paying attention in some embodiments that the CF layer and the TFT array are allocated on the same substrate.

In the present embodiment, the secondary second transparent electrode 223 is connected to the signal input of the relevant data line 211 to input the signal. The primary second transparent electrode 221 is not disposed at the location 222 on the second substrate 220 that corresponds to the relevant data line 211 where the parasitic capacitance occurred between the data line 211 and the primary second transparent electrode 221 is ignored (the distance between the data line 211 and the primary second transparent electrode 221 is longer). Despite the fact that the secondary second transparent electrode 223 is disposed at the location 222 on the second substrate 220 that corresponds to the relevant data line 211, the secondary second transparent electrode 223 inputs the same signal that is inputted to the relevant data line 211, which causes the parasitic capacitance in between the secondary second transparent electrode 223 and the data line 211 to approach zero. As the total parasitic capacitance in the data line 211 is diminished, the signal delay in the data line 211 is subsided, which avoids color spots due to oversized parasitic capacitance in the data line 211 of the liquid crystal display device 200.

According to FIG. 5, it is a flowchart of the method of reducing parasitic capacitance of the liquid crystal display device of the preferred embodiment of the present invention, which explains how to realize the structure of the liquid crystal display device of the first preferred embodiment.

STEP 501: by means of photolithography and patterning, the second transparent electrode is separated into a primary second transparent electrode 221 and a secondary second transparent electrode 223; and

STEP 502: offering the secondary second transparent electrode 223 the same signal to the relevant data line 211.

In the present embodiment, connecting the secondary second transparent electrode 223 to the signal input of the relevant data line 211 is a preferred realization of sending the secondary second transparent electrode 223 the same signal to the relevant data line 211.

In STEP 501, depositing the second transparent electrode on the second substrate 200 in the beginning, followed by photolithography and patterning that the second transparent electrode can be separated into the primary second transparent electrode 221 and the secondary second transparent electrode 223, which realizes the clear separation between the primary second transparent electrode 221 and the secondary second transparent electrode 223, where the secondary second transparent electrode 223 is located at the location 222 on the second substrate 220 that corresponds to the relevant data line 211, and the primary second transparent electrode 221 is located aside to the location 222 on the second substrate 220 that corresponds to the relevant data line 211.

In STEP 502, the secondary second transparent electrode 223 is provided with the same signal source that is inputted to the relevant data line 211, which enables the secondary second transparent electrode 223 and the relevant data line 211 to arrive at the same electric potential that eliminates the parasitic capacitance in between the secondary second transparent electrode 223 and the relevant data line 211.

As the total parasitic capacitance in the data line 211 is diminished, the signal delay in the data line 211 is subsided, which avoids color spots due to oversized parasitic capacitance in the data line 211 of the liquid crystal display device 200.

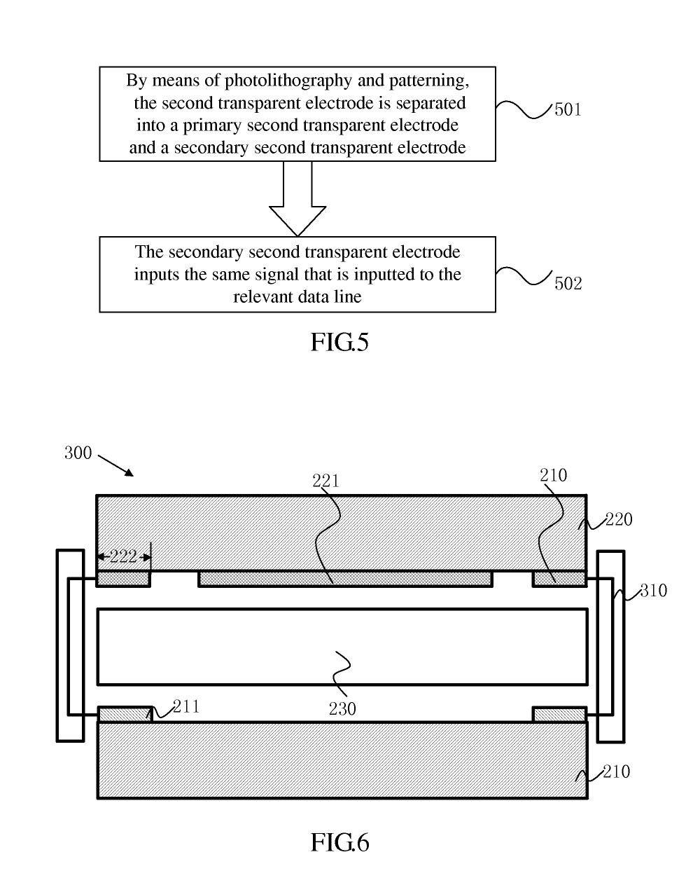

FIG. 6 is a schematic diagram of the structure of the liquid crystal display device of the second preferred embodiment of the present invention. The differences between the second preferred embodiment of the liquid crystal display device 300 and the first preferred embodiment lie in: the secondary second transparent electrode 223 is not connected to the signal input of the data line 211, and is connected to the data line 211 instead. In the embodiment, the secondary second transparent electrode 223 is connected to the data line 211 through a transfer 310, where the transfer 310 is disposed at inactive area of the liquid crystal display device 300.

In the present embodiment, the primary second transparent electrode 221 is separated from the location 222 on the second substrate 220 that corresponds to the data line 211, and the parasitic capacitance between the data line 211 and the primary second transparent electrode 221 is neglected. As the secondary second transparent electrode 223 is located at the location 222 on the second substrate 220 that corresponds to the data line 211, the secondary second transparent electrode 223 is connected to the data line 211 by means of a transfer 310 (the transfer is often used to connect the common line of the first substrate 210 to the data line located on the transparent electrode (for instance: the primary second transparent electrode 221) of the second substrate 220), which makes the secondary second transparent electrode 223 and the data line 211 to be at the same electric potential that substantially diminishes the parasitic capacitance between the secondary second transparent electrode 223 and the data line 211, and the overall parasitic capacitance in the data line 211 is dropped. Since the transfer 310 is disposed at the inactive area of the liquid crystal display device 300, the present embodiment is realized by connecting the data line 211 to the secondary second transparent electrode 223 through the transfer 310 after the fabrication of the first substrate 210, the second substrate 220 and the corresponding liquid crystal layer 230, which makes the secondary second transparent electrode 223 and the data line 211 to be at the same electric potential that eventually diminishes the overall parasitic capacitance of the data line 211.

The difference between the method of reducing the parasitic capacitance of the liquid crystal display device of the present invention and the method of the first preferred embodiment lie in: connecting the secondary second transparent electrode 223 to the signal source of the relevant data line 211 can be specifically realized by connecting the secondary second transparent electrode 223 to the relevant data line 211 through the transfer 310. Since the fabrication techniques of the transfer is matured, the present embodiment is realized in ease.

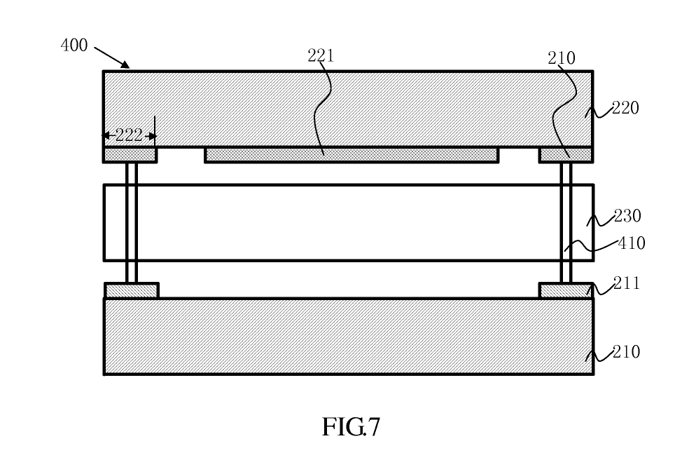

FIG. 7 is a schematic diagram of the structure of the liquid crystal display device of the third preferred embodiment of the present invention. The difference between the third preferred embodiment of the liquid crystal display device 400 and the first preferred embodiment lie in: the secondary second transparent electrode 223 is not connected to the signal input of the relevant data line 211, and is connected to the relevant data line 211 instead. In the embodiment, the secondary second transparent electrode 223 is connected to the relevant data line 211 through a conductive post 410 where the conductive post 410 is fabricated by adopting the technique for fabricating photo spacer. Therefore, the conductive post 410 is disposed at the active area of the liquid crystal display device 400, and the substances to fabricate the conductive post 410 generally are polymeric materials (polyphenylene sulfide; polyaniline and the like).

In the present embodiment, the primary second transparent electrode 221 is separated from the location 222 on the second substrate 220 that corresponds to the data line 211, and the parasitic capacitance between the data line 211 and the primary second transparent electrode 221 is neglected. As the secondary second transparent electrode 223 is located at the location 222 on the second substrate 220 that corresponds to the data line 211, the secondary second transparent electrode 223 is connected to the data line 211 by means of the conductive post 410, which makes the secondary second transparent electrode 223 and the data line 211 to be at the same electric potential that substantially diminishes the parasitic capacitance between the secondary second transparent electrode 223 and the data line 211 to zero, and the overall parasitic capacitance in the data line 211 is dropped.

The difference between the method of reducing the parasitic capacitance of the liquid crystal display device of the present invention and the method of the first preferred embodiment lie in: sending the secondary second transparent electrode 223 the same signal to the relevant data line 211 can be specifically embodied by connecting the secondary second transparent electrode 223 to the relevant data line 211 through the conductive post 410. Since the fabrication of the conductive post 410 has to be synchronized with that of the color filter layer, the conductive post 410 is then free of being affected by the consecutive processes, which means the sound electric conduction of the conductive post 410 is then assured.

In general, although a few embodiments of the present invention have been disclosed, the above preferred embodiments are not used for limiting this invention, and it will be understood by those of ordinary skill in the art that various changes in form and details may be made therein without departing from the spirit and scope of the present invention.

What is claimed is:

1. A method of reducing parasitic capacitance of liquid crystal display device, where the liquid crystal display device comprises a first substrate, a second substrate and a liquid crystal layer disposed in between the first substrate and the second substrate, the first substrate comprises data lines and a first transparent electrode, and the second substrate is provided with a second transparent electrode, characterized in that: the method comprises the following steps:
A. by means of photolithography and patterning, the second transparent electrode being separated into a primary second transparent electrode and a secondary second transparent electrode;
B. offering the secondary second transparent electrode the same signal inputted to the relevant data line;
the secondary second transparent electrode being located at a location on the second substrate that corresponds to the relevant data line, and the primary second transparent electrode being located aside to the location on the second substrate that corresponds to the relevant data line;
the step B, more specifically, to connect the secondary second transparent electrode to the signal input of the relevant data line, or to the relevant data line.

2. A method of reducing parasitic capacitance of liquid crystal display device, where the liquid crystal display device comprises a first substrate, a second substrate and a liquid crystal layer disposed in between the first substrate and the second substrate, the first substrate comprises data lines and a first transparent electrode, and the second substrate is provided with a second transparent electrode, characterized in that: the method comprises the following steps:
A. by means of photolithography and patterning, the second transparent electrode being separated into a primary second transparent electrode and a secondary second transparent electrode;
B. offering the secondary second transparent electrode the same signal inputted to the relevant data line;
the secondary second transparent electrode being located at a location on the second substrate that corresponds to the relevant data line, and the primary second transparent electrode being located aside to the location on the second substrate that corresponds to the relevant data line.

3. The method of reducing parasitic capacitance of liquid crystal display device as claimed in claim 2, characterized in that: the step B specifically is: to connect the second transparent electrode to the signal input of the relevant data line.

4. The method of reducing parasitic capacitance of liquid crystal display device as claimed in claim 2, characterized in that: the step B specifically is: to connect the second transparent electrode to the relevant data line.

5. The method of reducing parasitic capacitance of liquid crystal display device as claimed in claim 4, characterized in that: the connection between the second transparent electrode and the relevant data line is specifically embodied by connecting the second transparent electrode to the relevant data line through a transfer.

6. The method of reducing parasitic capacitance of liquid crystal display device as claimed in claim 5, characterized in that: the transfer is disposed at an inactive area of the liquid crystal display device.

7. The method of reducing parasitic capacitance of liquid crystal display device as claimed in claim 4, characterized in that: the connection between the second transparent electrode and the relevant data line is specifically embodied by connecting the second transparent electrode to the relevant data line through a conductive post.

8. The method of reducing parasitic capacitance of liquid crystal display device as claimed in claim 7, characterized in that: the conductive post is disposed at an active area of the liquid crystal display device.

9. A liquid crystal display device, comprising: a first substrate, a second substrate and a liquid crystal layer disposed in between the first substrate and the second substrate, the first substrate comprising data lines and a first transparent electrode, and the second substrate being provided with a second transparent electrode, characterized in that: the second transparent electrode comprises a primary second transparent electrode and a secondary second transparent electrode, wherein the secondary second transparent electrode is to receive the signal of the relevant data line and is located at a location on the second substrate that corresponds to the relevant data line while the primary second transparent electrode is located aside to the location on the second substrate that corresponds to the relevant data line.

10. The liquid crystal display device as claimed in claim 9, characterized in that:
the secondary second transparent electrode is connected to the signal input of the relevant data line.

11. The liquid crystal display device as claimed in claim 9, characterized in that:
the secondary second transparent electrode is connected to the relevant data line.

12. The liquid crystal display device as claimed in claim 11, characterized in that:
the secondary second transparent electrode is connected to the relevant data line through a transfer.

13. The liquid crystal display device as claimed in claim 12, characterized in that:
the transfer is disposed at an inactive area of the liquid crystal display device.

14. The liquid crystal display device as claimed in claim 11, characterized in that:
the secondary second transparent electrode is connected to the relevant data line through a conductive post.

15. The liquid crystal display device as claimed in claim 14, characterized in that:
the conductive post is disposed at an active area of the liquid crystal display device.
